(19) United States
(12) Patent Application Publication
(10) Pub. No.: US 2021/0053179 A1
(43) Pub. Date: Feb. 25, 2021

(54) Novel CMP Pad Design and Method of Using the Same

(71) Applicant: Taiwan Semiconductor Manufacturing Company, Ltd., Hsinchu (TW)

(72) Inventors: Pin-Chuan Su, Hsinchu (TW); Jeng-Chi Lin, Hsinchu (TW); Guan-Yi Lee, Hsinchu (TW); Hui-Chi Huang, Zhubei City (TW); Kei-Wei Chen, Tainan City (TW)

(21) Appl. No.: 16/549,153

(22) Filed: Aug. 23, 2019

(51) Int. Cl. B24B 37/20; H01L 21/306; H01L 21/321

(52) U.S. Cl. CPC B24B 37/20; H01L 21/3212; H01L 21/30625

(57) ABSTRACT

An embodiment is a polishing pad including a top pad and a sub pad that is below and contacting the top pad. The top pad includes top grooves along a top surface and microchannels extending from the top grooves to a bottom surface of the top pad. The sub pad includes sub grooves along a top surface of the sub pad.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

Chemical-mechanical polishing (CMP), or chemical-mechanical planarization, has become an important semiconductor manufacturing process since its introduction in the 1980s. An example application of the CMP process is the formation of copper interconnects using the damascene/dual-damascene process, where the CMP process is used to remove metal (e.g., copper) deposited outside trenches formed in a dielectric material. The CMP process is also widely used to form a planar device surface at various stages of semiconductor manufacturing because the photolithography and etching processes used to pattern the semiconductor devices may need a planar surface to achieve the targeted accuracy. As the semiconductor manufacturing technology continues to advance, better CMP tools are needed to meet the more stringent requirements of advanced semiconductor processing.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C illustrate side view cross-sections of a chemical-mechanical polishing (CMP) system, including a polishing pad, in accordance with some embodiments.

FIGS. 2A-2C, 3A-3C, and 4A-4C illustrate top-down and side view cross-sections of various CMP systems, in accordance with some embodiments.

FIGS. 5A-5B are schematics of polishing pads, in accordance with some embodiments.

FIGS. 6A-6C, 7A-7E, and 8A-8E illustrate top-down cross-sections of components of various polishing pads, in accordance with some embodiments.

FIGS. 9A-9B, 10A-10B, 11A-11B, 12A-12D, 13A-13B, 14A-14B, 15A-15B, 16A-16B, 17A-17B, and 18A-18B are schematics of polishing pads and/or components of polishing pads, in accordance with some embodiments.

FIG. 19 is a flowchart, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features need not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Throughout the manufacture of a semiconductor device, the semiconductor wafer undergoes a large number of process steps. One of the most frequent steps involves undergoing chemical-mechanical polishing (CMP). The CMP step is intended to smooth the surface of, or planarize, the wafer before, in between, and after various other steps in the manufacturing process.

Typically, during the CMP step, the surface of the wafer to be smoothed is held face down against a broad surface of a polishing pad. The wafer and/or the polishing pad will rotate. If both rotate, then they may rotate in the same or opposite directions. Between the wafer and polishing pad is a corrosive chemical slurry which acts as an abrasive to aid in polishing the surface of the wafer. The slurry usually includes a liquid with solid abrasives suspended in the liquid.

The dynamic action of the rotating wafer and polishing pad along with the chemical properties and abrasiveness of the slurry are intended to level the topography of the wafer. The surface imperfections and uneven topography of the wafer essentially means that irregular portions extend outward from the general surface of the wafer. Aided by the rotations of the wafer and the polishing pad, the chemical properties and the abrasiveness of the slurry level those irregular portions by removing them from the wafer, particle-by-particle. In addition, often times the polishing pad will undergo some degree of breakdown during a CMP process or repeated CMP processes, causing loose polishing pad particles to mix into the slurry. The combination of the particles removed from the wafer and the polishing pad may be collectively referred to as debris. This debris generally remains within the slurry between the wafer and polishing pad and only leaves the system with any outflow of slurry from the edge of the polishing pad. Note that the following disclosure will generally refer to the removed particles from the wafer; however, it can be understood that polishing pad debris and other debris may be included therein.

Due to the frequency of the CMP steps in semiconductor manufacturing, improving the polishing and the removal rate of surface imperfections can have a significant impact on the entire manufacturing process. The additional benefits of an improved CMP step may include: better planarization, improved thickness uniformity, decreased under-polishing, and higher polishing removal rate.

While the slurry, and any abrasives included within, may be designed to make contact with the surface of the wafer and remove particles to planarize the wafer, those removed particles may also make contact with the surface of the wafer. However, those removed particles may vary greatly in size and material composition. As such, they are not designed to improve the planarization of the wafer. In fact, depending on the characteristics of those removed particles, they may inhibit the ability of the slurry to effectively planarize the wafer. For example, a removed particle that is particularly large, abrasive, and or irregularly shaped may make contact with a planarized portion of the wafer and cause the removal of additional particles thereby causing that portion of the wafer to become uneven once again.

In light of the foregoing, the disclosed polishing pads comprise conduits for those removed particles to be drawn away from the wafer and leave the CMP system in such a way that minimizes the chances that those removed particles will continue to make abrasive contact with the wafer before leaving the CMP system.

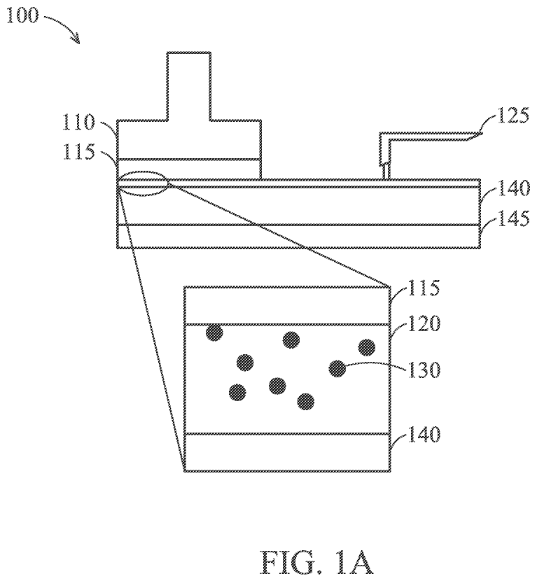

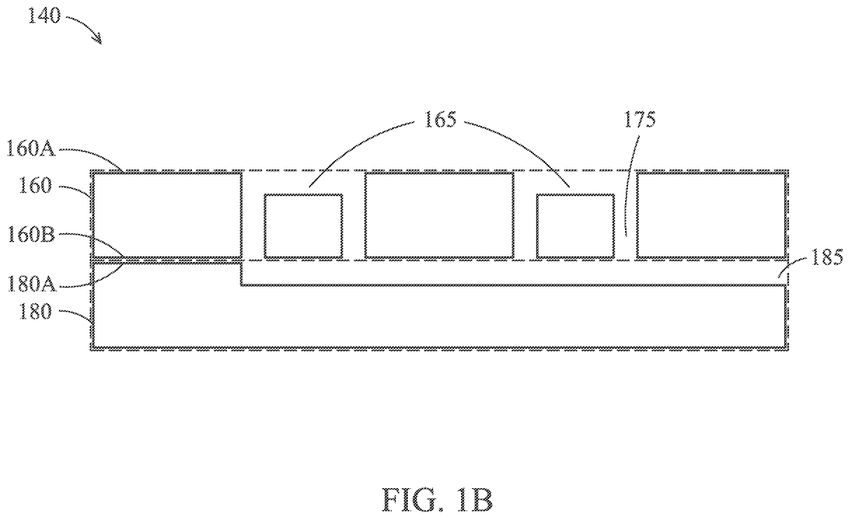

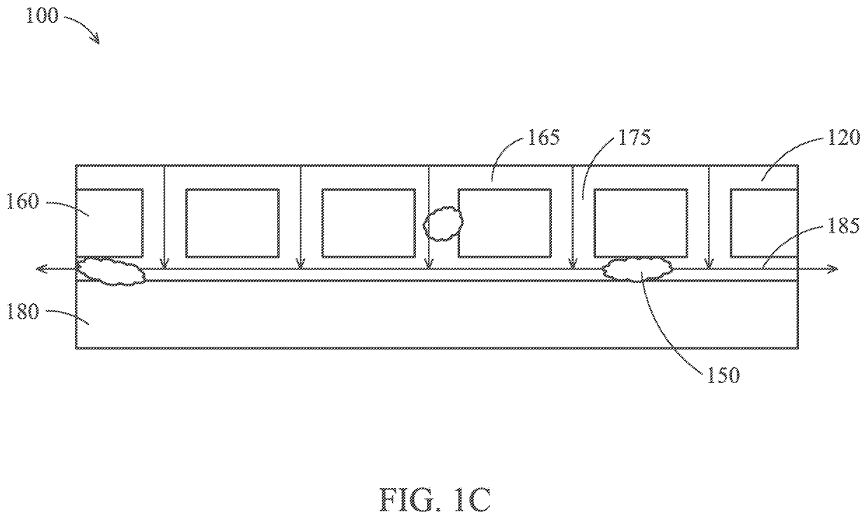

Referring to FIG. 1A, in a typical CMP system 100, a head 110 holds a wafer 115 such that the surface of the wafer 115 to be polished is pressed against a slurry 120 disposed over a polishing pad 140, the polishing pad attached to a platen 145. A dispenser 125 may dispense the slurry 120 onto the polishing pad 140 before the polishing and/or throughout the polishing. The slurry 120 may comprise water, abrasives, chelator, inhibitor, pH adjuster, or any combination thereof. The chelator may comprise one or more of molybdate, glutamic acid, diphosphine, and/or the like. The inhibitor may comprise one or more of phosphate, nitrate, carboxylic acid, and/or the like. The wafer 115 need not make direct contact with the polishing pad 140—the slurry 120 being interposed therebetween. Abrasives 130 may be distributed throughout the slurry 120. Those abrasives may include colloidal silica, aluminum, cerium oxide, or any combination thereof.

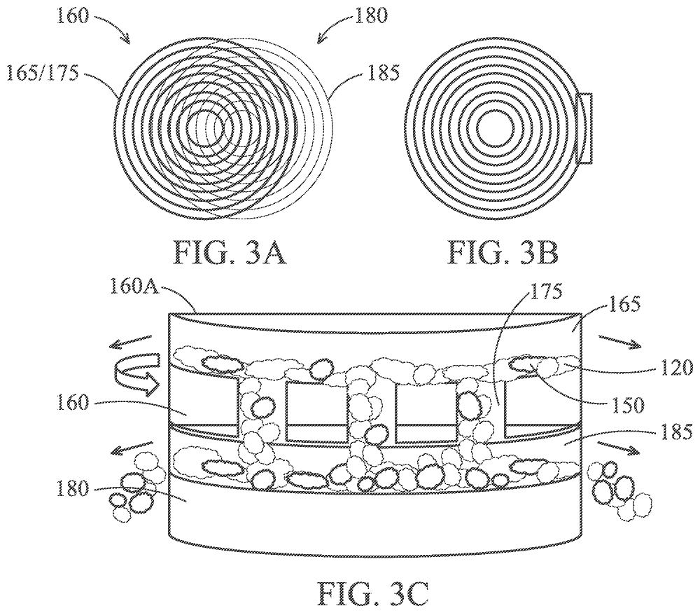

The slurry 120 is typically dispensed on a portion of the polishing pad 140 away from where the wafer 115 makes contact with the slurry 120. Centrifugal forces from the rotations of the wafer 115 and the polishing pad 140 cause some of the slurry 120, some abrasives 130, and some removed particles 150 to exit the CMP system 100 at the edges of the wafer 115 and the polishing pad 140 (e.g., similarly as depicted and later described in FIG. 3C and other figures).

Referring to FIG. 1B, showing a side view cross-section of the polishing pad 140, the polishing pad 140 may have an upper portion called a top pad 160 (outlined with a dotted line) and a lower portion called a sub pad 180 (outlined with a dotted line). The top pad 160 and the sub pad 180 may be formed of the same or different materials and may have the same or different hardnesses and textures. The top pad 160 and the sub pad 180 may be secured or attached to one another to ensure that they do not move independently from one another. As further described in this disclosure, the top pad 160 may have top grooves 165 along and within a top surface 160A of the top pad 160. In addition, the top pad 160 may have microchannels 175 extending from the top grooves 165 (or from the top surface 160A) to a bottom surface 160B of the top pad 160. Similarly, the sub pad 180 may have sub grooves 185 along and within a top surface 180A of the sub pad 180. As will be discussed in detail below, the polishing pad may comprise a variety of patterns of the top grooves 165, the microchannels 175, and the sub grooves 185.

The top pad 160 may be attached to the sub pad 180 in a variety of ways. For example, the polishing pad 140 may be manufactured or permanently assembled with the top pad 160 fixed to the sub pad 180, such as with an adhesive, screws, or other means (not shown in the figures). Alternatively, the top pad 160 and the sub pad 180 may each comprise components allowing them to be interchangeably attached to one another. For example, a temporary adhesive (not shown in the figures) may hold them attached during use while also permitting them to be separated in order to be cleaned individually. In addition to or instead of an adhesive, the top pad 160 and the sub pad 180 may each comprise clamps, such that the top pad 160 has clamps (not shown) along its lower outer edge and the sub pad 180 has clamp holders or hubs (not shown), or vice versa. The top pad 160 and the sub pad 180 may each have clamps and clamp hubs to facilitate an interlocking type of attachment.

The temporary and/or interchangeable attachment system serves several benefits. For example, it allows the user to select a desired combination of the top pad 160 and the sub pad 180 to achieve the specifications for the particular CMP process needed. In one embodiment, if the polishing is expected to produce relatively many, large, and/or abrasive removed particles, then the desired top pad 160 may have wider or deeper top grooves 165 and/or wider microchannels 175 and sub grooves 185 to ensure the removed particles have sufficient space in the conduit system to be effectively removed from the CMP system 100. In another embodiment, when the CMP process is expected to remove only a relatively few, small, and/or soft removed particles, then the conduit system may benefit from a different combination of the top pad 160 and the sub pad 180. For example, in those cases, the top grooves 165 may be narrower or shallower and the microchannels 175 and the sub grooves 185 may be narrower. The narrower the top grooves 165, the greater the polishing surface area for the top pad 160, which may allow for greater precision and control during the CMP process. As shown later in several figures, many other combinations regarding the dimensions of the top pad 160 and the sub pad 180 can selected to serve a variety of purposes and needs. Further, one combination may be used for the initial polishing and other combinations used for the remaining polishing within a single CMP process step.

Referring to FIG. 1C, a side view cross-section of the CMP system 100 depicts the slurry 120 and removed particles 150 flowing through the grooves and microchannels. The grooves and microchannels serve as conduits to improve the movement of the slurry 120 and the removed particles 150 through and away from the wafer 115 and the polishing pad 140. Specifically, the grooves and microchannels are designed to allow any removed particles 150 to leave the CMP system 100 with minimal physical contact with the surface of the wafer 115. The CMP system may dispose of the mixture or, alternatively, include a method to remove the debris in order to recycle the slurry 120. As alluded to above, due to the rotations of the wafer 115 and the polishing pad 140—as well as friction between the slurry 120 and the wafer 115 and the polishing pad 140—the removed particles 150 (along with the slurry 120) will have a tendency to move outwardly (or radially) from the centers of the wafer 115 and the polishing pad 140. In addition, the removed particles 150—especially those having a higher specific gravity than the slurry 120—will have a tendency to be drawn closer to the polishing pad 140 than to the wafer 115 simply due to gravity. As such, during polishing the removed particles 150 will tend to move downward and outward from the wafer 115. The grooves (e.g., the top grooves 165 and the sub grooves 185) as well as the microchannels 175 facilitate this general flow of slurry 120 and the removed particles 150.

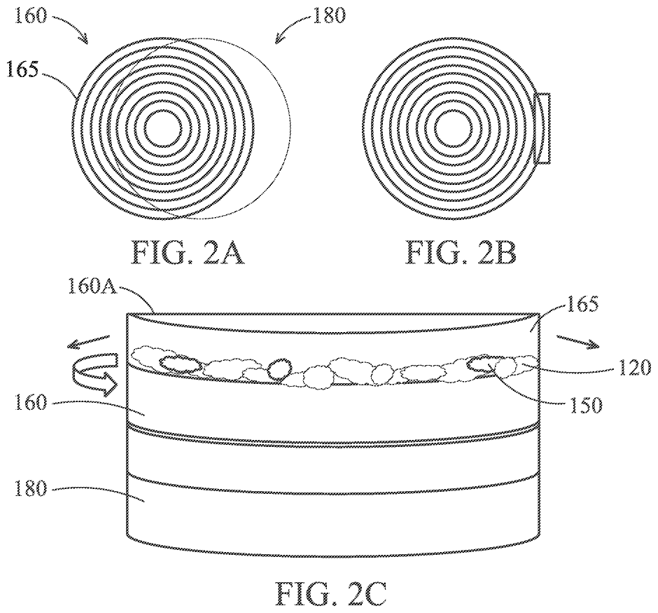

Referring to FIGS. 2A-C, top views and a side view cross-section of the CMP system 100 depict the polishing pad 140 comprising the top pad 160 having top grooves 165 but not having any microchannels, while the sub pad 180 does not have any grooves. FIG. 2A depicts the top pad 160 laterally displaced from the sub pad 180 to show these components separately, while FIG. 2B depicts them aligned as they exist in the form of the polishing pad 140. FIG. 2C depicts the side view cross-section of the CMP system at the portion of FIG. 2B identified with a rectangle. As shown in FIG. 2C, the slurry 120 and removed particles 150 remain along the top surface 160A of the top pad 160 and in the top grooves 165 until they can be expelled from the outer edge of the polishing pad 140.

Referring to FIGS. 3A-C, top views and a side view cross-section of the CMP system 100 depict the polishing pad 140 comprising the top pad 160 having top grooves 165 and microchannels 175, while the sub pad 180 had sub grooves 185. FIG. 3A depicts the top pad 160 laterally displaced from the sub pad 180 to show these components separately, while FIG. 3B depicts them aligned as they exist in the form of the polishing pad 140. FIG. 3C depicts the side view cross-section of the CMP system at the portion of FIG. 3B identified with a rectangle. As shown in FIG. 3C, the slurry 120 and removed particles 150 are able to flow between the top pad 160 and the sub pad 180 through the grooves and microchannels. It should be noted however, that, due to the concentric circle pattern of the sub grooves 185 (as shown in FIGS. 3A and 3B), the only path for the slurry 120 and the removed particles 150 to be expelled at the sub pad 180 level is at the outermost circle located at the outermost edge of the polishing pad 140. This means that any slurry 120 and removed particles 150 that pass through the microchannels 175 located within any inner regions of the polishing pad 140 will reach sub grooves 185 that do not eventually lead to an exit from the polishing pad 140. While that slurry 120 and those removed particles 150 may be conveniently drawn away from the wafer 115, it is possible that they eventually accumulate within those inner microchannels 175 and sub grooves 185.

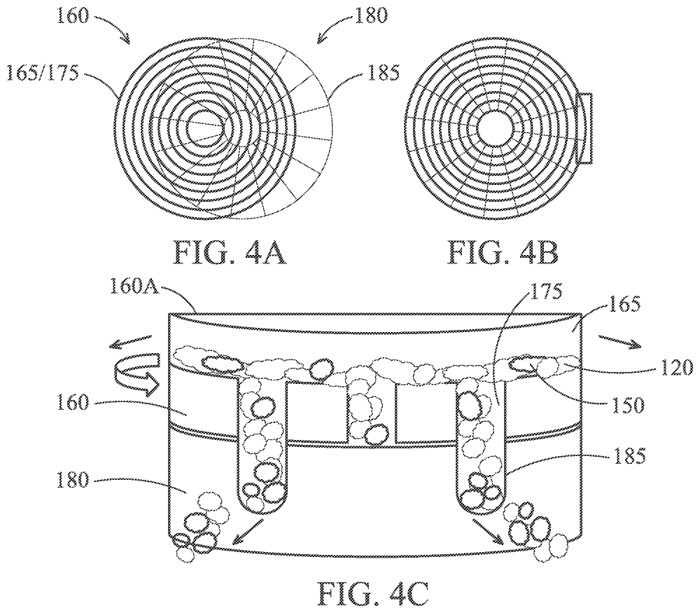

Referring to FIGS. 4A-C, top views and a side view cross-section of the CMP system 100 also depict the polishing pad 140 comprising the top pad 160 having top grooves 165 and microchannels 175, while the sub pad 180 had sub grooves 185. FIG. 4A depicts the top pad 160 laterally displaced from the sub pad 180 to show these components separately, while FIG. 4B depicts them aligned as they exist in the form of the polishing pad 140. FIG. 4C depicts the side view cross-section of the CMP system at the portion of FIG. 4B identified with a rectangle. Similar to the previous set of figures, as shown in FIG. 4C, the slurry 120 and removed particles 150 are able to flow between the top pad 160 and the sub pad 180 through the grooves and microchannels. However, now the radial pattern of the sub grooves 185 (as shown in FIGS. 4A and 4B), provides a path for all slurry 120 and removed particles 150 that pass through the microchannels 175 to the sub grooves 185 to exit the polishing pad 140 at the sub pad 180 level via one of the radial spokes.

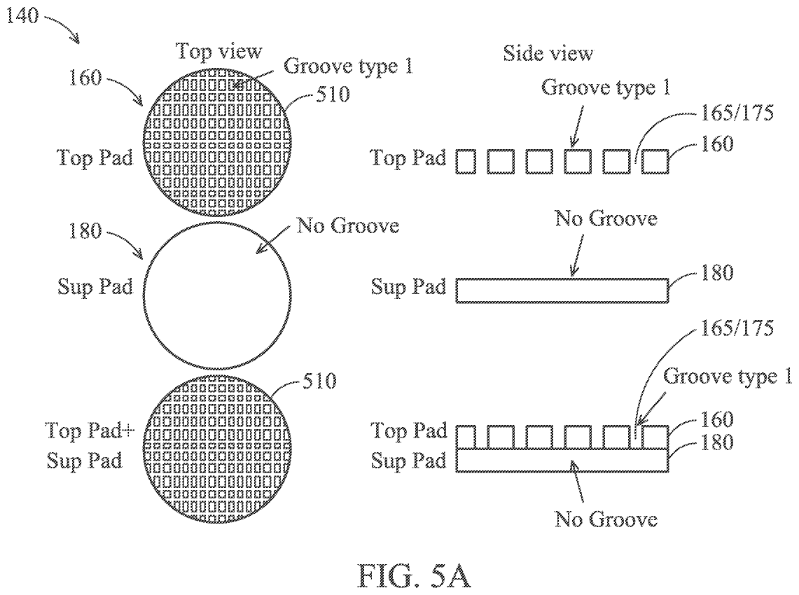

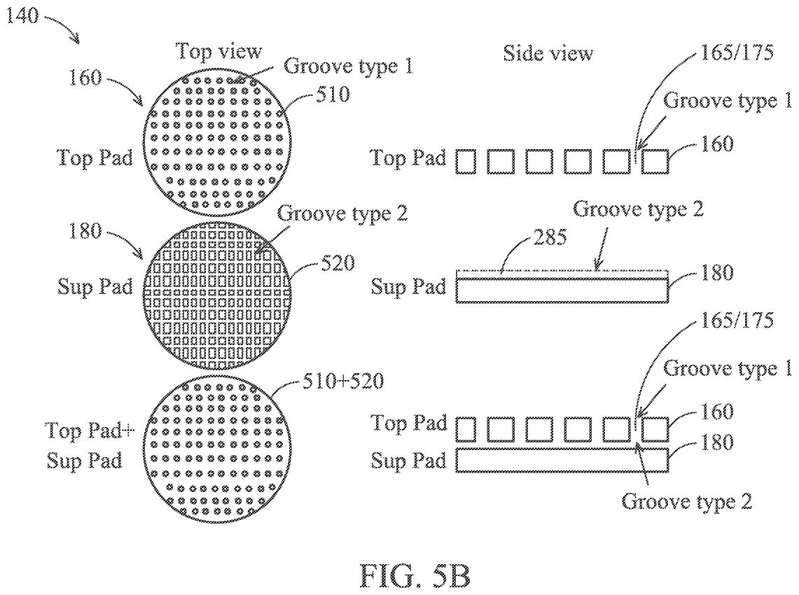

Referring to FIG. 5A, the polishing pad 140 may comprise the top pad 160 and the sub pad 180. In some embodiments, the polishing pad 140 may comprise top grooves 165 arranged in a first pattern 510. In some embodiments, the top pad 160 may further comprise microchannels 175 extending entirely through the top pad 160 to the sub pad 180. In this example and for simplicity, the pattern of the top grooves 165 and the microchannels 175, collectively, may compose the first pattern 510.

Still referring to FIG. 5A, the sub pad 180 need not have any grooves. As such, the combination of all grooves (i.e., the top grooves 165 and the microchannels 175) of the polishing pad 140 has the first pattern 510.

Referring to FIG. 5B, the polishing pad 140 may comprise the top pad 160 and the sub pad 180. The polishing pad 140 may comprise top grooves 165 arranged in the first pattern 510. In some embodiments, the top pad 160 may further comprise microchannels 175 extending entirely through the top pad 160 to the sub pad 180. In this example and for simplicity, the pattern of the top grooves 165 and the microchannels 175, collectively, may compose the first pattern 510.

Still referring to FIG. 5B, the sub pad 180 may comprise sub grooves 185 arranged in a second pattern 520. The second pattern 520 may be the same or different from the first pattern 510. As such, the combination of all grooves and microchannels (i.e., the top grooves 165, the microchannels 175, and the sub grooves 185) of the polishing pad 140 has the first pattern 510 and the second pattern 520 combined.

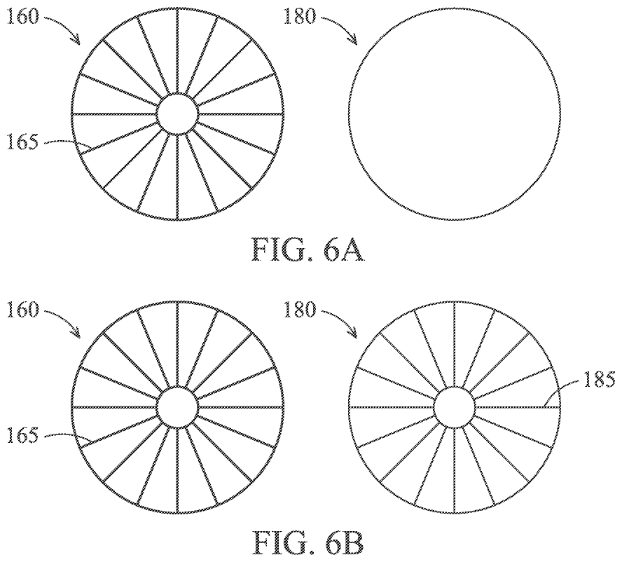

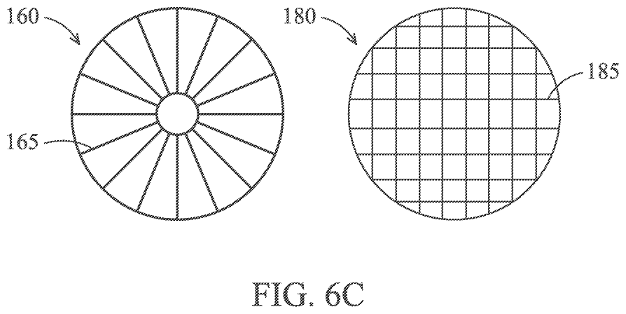

Referring to FIGS. 6A-C, depicting various combinations of top pad and sub pad patterns, the patterns of the grooves and microchannels may be selected to facilitate the movement of the removed particles 150 from the CMP system 100. For example, with respect to FIG. 6A, the top pad may have a pattern of top grooves 165, and the sub pad need not have any grooves. With respect to FIG. 6B, the top pad may have a pattern of top grooves 165 and microchannels 175, and the sub pad may have an identical pattern of sub grooves 185. With respect to FIG. 6C, the top pad may have a pattern of top grooves 165 and microchannels 175, and the sub pad may have a different pattern of sub grooves 185.

While there may be quite a few patterns and combinations of patterns that will be effective in various CMP systems 100 (with respect to material compositions of the wafer 115, the polishing pad 140, and the slurry 120) and the objectives of the particular CMP step, certain patterns and combinations may be better than others. For example, it may be preferable for the sub grooves 185 of the sub pad 180 to have radial components, especially with those radial components reaching the outer edge of the sub pad 180. Such a pattern is helpful because those radial components work with the centrifugal force to help expel the removed particles 150 as well as the slurry 120 from the edge of the sub pad 180. Even if the sub grooves 185 of the sub pad 180 do not extend directly outward from a center of the sub pad 180 in a radial direction, they may simply have components extending from an inner portion of the sub pad 180 to the outer perimeter of the sub pad 180. Conversely, without radial components or components extending to the outer edge, any removed particles 150 and slurry 120 that reach the sub pad 180 may accumulate within the sub grooves 185 causing a buildup in the sub grooves 185 and the microchannels 175 and potentially reducing the benefit that the sub grooves 185 are otherwise intended to provide. Nonetheless, it is possible for manufacturers to want a CMP system 100 wherein the removed particles 150 are generally drawn downward with the aid of top grooves 165 and microchannels 175 toward the sub pad 180 without necessarily being expelled outward from the sub pad 180.

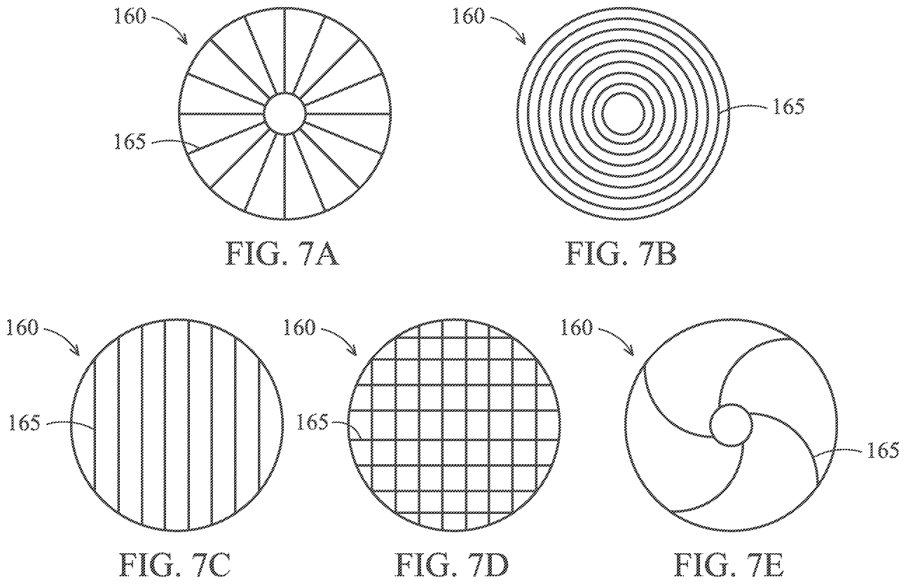

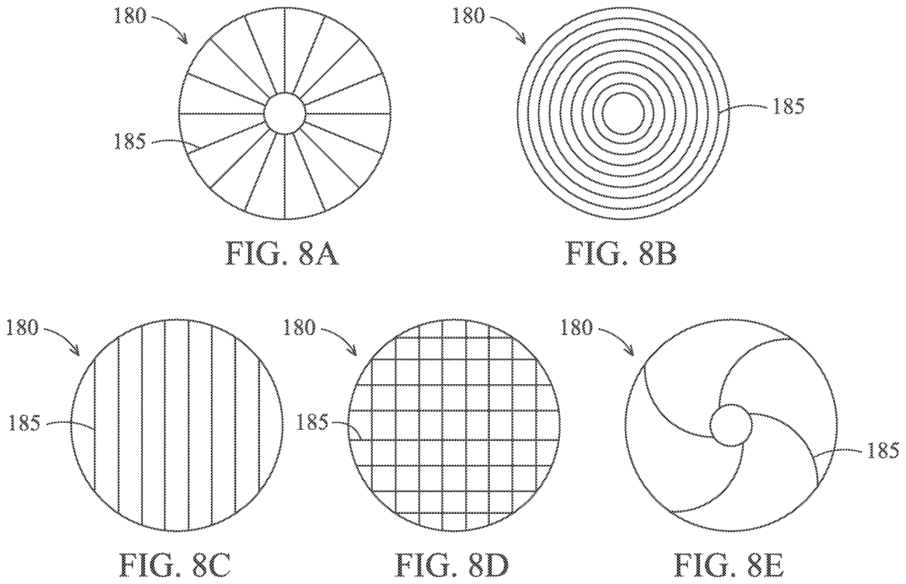

Referring to FIGS. 7A-E, top-down views of the top pad 160 depict various patterns for the top grooves 165 and microchannels 175 in the top pad 160. Referring to FIGS. 8A-E, top-down views of the sub pad 180 depict various patterns for the sub grooves 185 in the sub pad 180. Those patterns may comprise radial spokes, concentric circles, parallel lines, perpendicular or non-perpendicular X-Y grid lines, and/or spirals. Other patterns and combinations of patterns may be used as well.

It should further be noted that the patterns featured in the top pad 160 and the sub pad 180 need not comprise continuous lines. Indeed, although depicted in the figures as continuous lines, the patterns may comprise line segments or combinations of continuous lines and line segments. For example, the pattern featured in the top pad 160 may comprise line segments, while the pattern featured in the sub pad 180 may comprise continuous lines. The purpose of such a combination may be to maximize the surface area of the top surface 160A, which is instrumental in the CMP process.

In addition, the microchannels 175 may or may not align with the pattern of the top grooves 165. Or some of the microchannels 175 may align with the pattern of the top grooves 165 while other microchannels 175 may be located in other areas of the top pad 160. However, it may be appreciated that the microchannels 175 may be more effective if they align with the top grooves 165 rather than extending from other areas of the top pad 160. Furthermore, the microchannels 175 may or may not align with the pattern of the sub grooves 185. Or some of the microchannels 175 may align with the pattern of the sub grooves 185 while other microchannels 175 may be located above other areas of the sub pad 180. However, it may be appreciated that the microchannels 175 may be more effective if they align with the sub grooves 185 rather than being located above other areas of the sub pad 180. As such, the pattern of the microchannels 175 is likely to be most effective if it aligns with both the pattern of the top grooves 165 and the pattern of the sub grooves 185, regardless of whether the top grooves 165 and the sub grooves 185 have the same patterns.

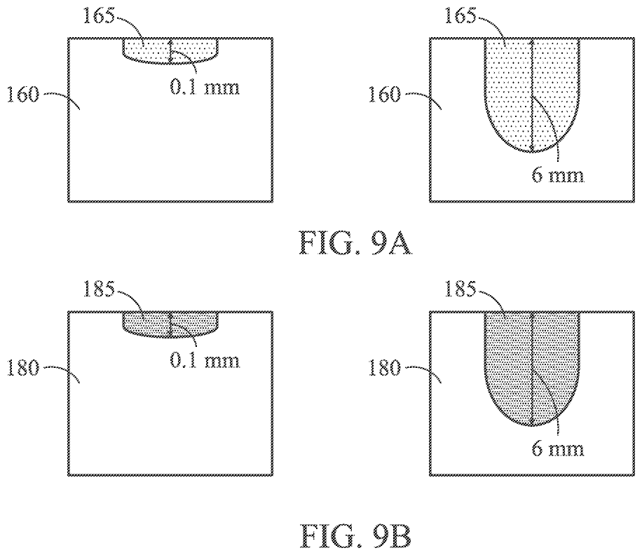

Referring to FIGS. 9A and 9B, the top grooves 165 and the sub grooves 185 may have the same or different depths from the top surfaces of the top pad 160 and the sub pad 180, respectively. For example, the grooves may have depths between about 0.1 mm and about 20 mm, depending on the particular CMP process details. In an embodiment, the sub grooves 185 may have a greater depth than the top grooves 165 in order to accommodate for more of the slurry 120 and the removed particles 150 to be drawn downward through the microchannels 175 to the sub pad 180 due to gravity and agitation by the rotating polishing pad 140.

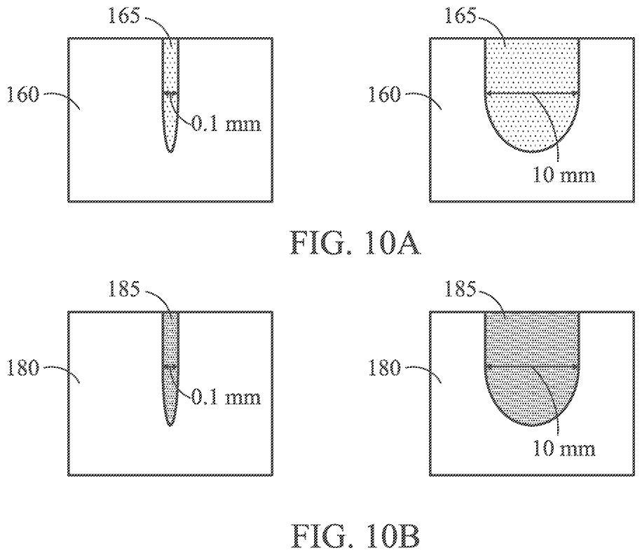

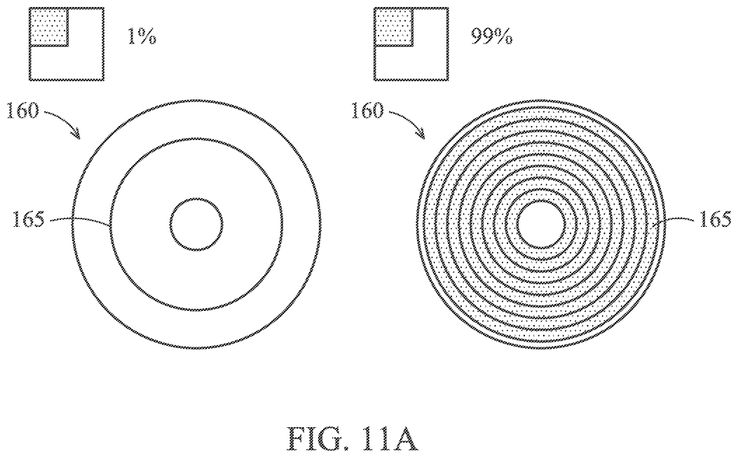

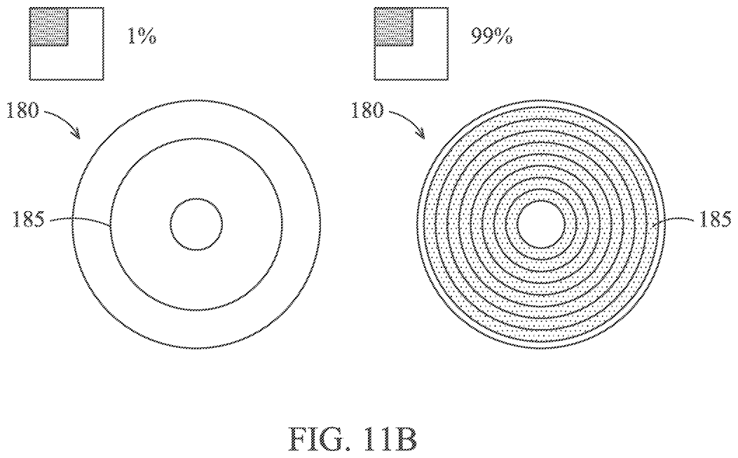

Referring to FIGS. 10A and 10B, the top grooves 165 and the sub grooves 185 may have the same or different widths along the top surfaces of the top pad 160 and the sub pad 180, respectively. For example, the grooves may have widths between about 0.1 mm and about 10 mm, depending on the particular CMP process details. In an embodiment, the sub grooves 185 may have a greater width than the top grooves 165 in order to accommodate for more of the slurry 120 and the removed particles 150 to be drawn downward through the microchannels 175 to the sub pad 180 due to gravity and agitation by the rotating polishing pad 140.

Referring to FIGS. 11A and 11B, the total coverage of the top grooves 165 and the sub grooves 185 along the top surfaces of the top pad 160 and the sub pad 180, respectively, may be the about the same or different. For example, the total coverage of the grooves may be between about 1% and 99%, or between about 1% and about 20%, depending on the particular CMP process details. In an embodiment, the sub grooves 185 may comprise a greater total coverage of the sub pad 180 than the top grooves 165 total coverage of the top pad 160 in order to accommodate for more of the slurry 120 and the removed particles 150 to be drawn downward through the microchannels 175 to the sub pad 180 due to gravity and agitation by the rotating polishing pad 140.

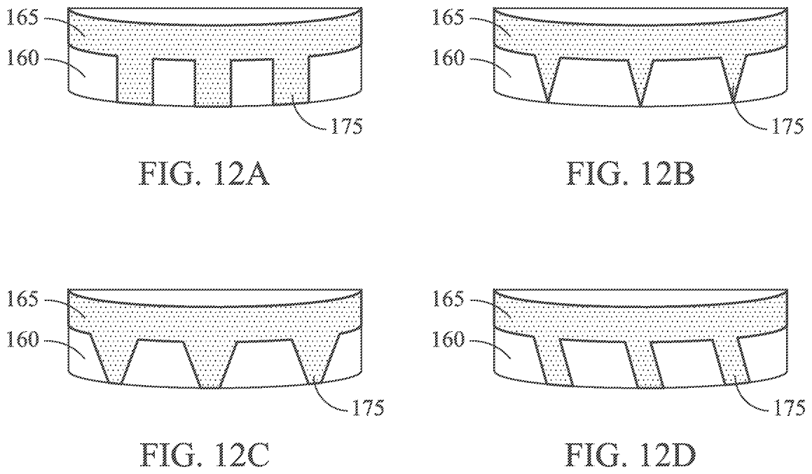

Referring to FIGS. 12A-12B, the microchannels 175 may comprise various side view cross-sectional shapes. For example, the microchannels 175 may be rectangular (FIG. 12A), triangular (FIG. 12B), trapezoidal (FIG. 12C), parallelogramical (FIG. 12D), or any combination thereof. It should be noted that the triangular shaped microchannels 175 need not literally come to a point because typically it would be preferable to have a smallest width that would still permit the slurry 120 and the removed particles 150 to pass through to the sub pad 180. It should be further noted that the parallelogramical shaped microchannels 175 have a slanted angle such that they are not perpendicular to the top surface 160A or bottom surface 160B of the top pad 160. In addition, the side view cross-sections of any of the shapes may have concave or convex sidewalls (not specifically depicted in the figures). From a top-down view, although the microchannels 175 may comprise various shapes, it is more feasible that they are round or circular shaped (not specifically depicted in the figures) and less feasible that they are rectangular or diamond shaped.

As shown in FIG. 12A, to the extent the microchannels 175 have a rectangular shape from a side view cross-section and a circular shape from a top-down view, each microchannel 175 will have an overall cylindrical shape. As shown in FIGS. 12B or 12C, to the extent the microchannels 175 have a triangular or trapezoidal shape from a side view cross-section and a circular shape from a top-down view, then each microchannel 175 will have an overall conical shape. As shown in FIG. 12D, to the extent the microchannels 175 have a parallelogramical shape from a side view cross-section and a circular shape from a top-down view, each microchannel 175 will have an overall oblique cylindrical shape. In the case of an oblique cylindrical shape, the microchannels 175 may be angled downward and outward from the center of the top surface 160A of the top pad 160. The purpose of such a geometry is to facilitate the movement of the slurry 120 and the removed particles 150 from the top pad 160 to the sub pad 180 caused by gravity and the centrifugal force from the rotation of the polishing pad 140.

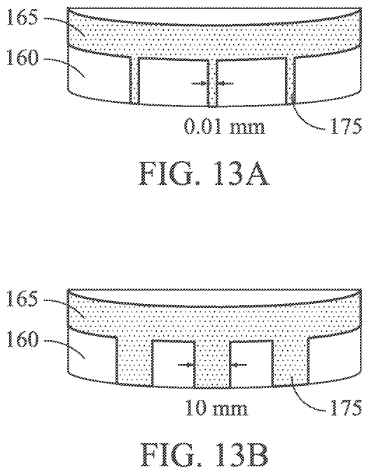

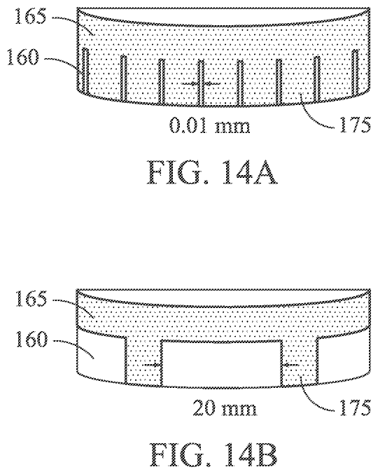

Referring to FIGS. 13A and 13B, the microchannels 175 may have widths between about 0.01 mm and 10 mm. For embodiments in which the microchannels 175 have a varying width from the top surface 160A of the top pad 160 to the bottom surface 160B of the top pad 160, all of the widths will fall somewhere within this particular range of dimensions. Referring to FIGS. 14A and 14B, the lateral distance between adjacent microchannels 175 may be between about 0.01 mm and 20 mm.

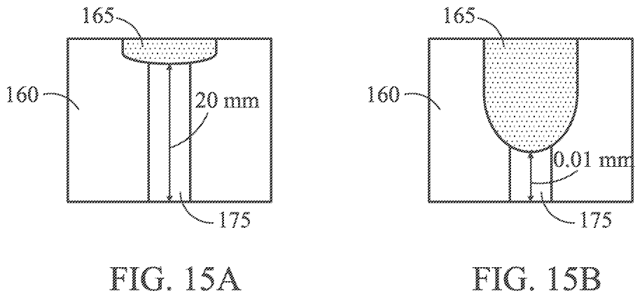

Referring to FIGS. 15A and 15B, the microchannels 175 may have depths between about 0.01 mm and about 20 mm. As can be seen in the figures, the depths of the microchannels 175 are related to the thickness of the top pad 160 as well as the depth of the top grooves 165. That is, the sum of the depth of the top grooves 165 and the depth of the microchannels 175 should equal the thickness of the top pad 160. In the event that a microchannel 175 does not align with a top groove 165, then the depth of that microchannel 175 will be the same as the thickness of the top pad 160.

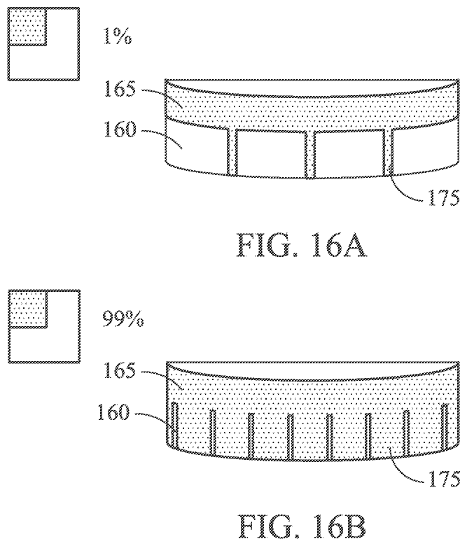

Referring to FIGS. 16A and 16B, the total coverage of the microchannels across a top-down view of the top pad 160 may be between about 1% and 99%, or between about 1% and about 20%, depending on the particular CMP process details. In an embodiment, the microchannels 175 may comprise a lesser total coverage of the top pad 160 than that of the top grooves 165 total coverage of the top pad 160. In addition, the microchannels 175 may comprise a lesser total coverage of the top pad 160 than that of the sub grooves 185 total coverage of the sub pad 180.

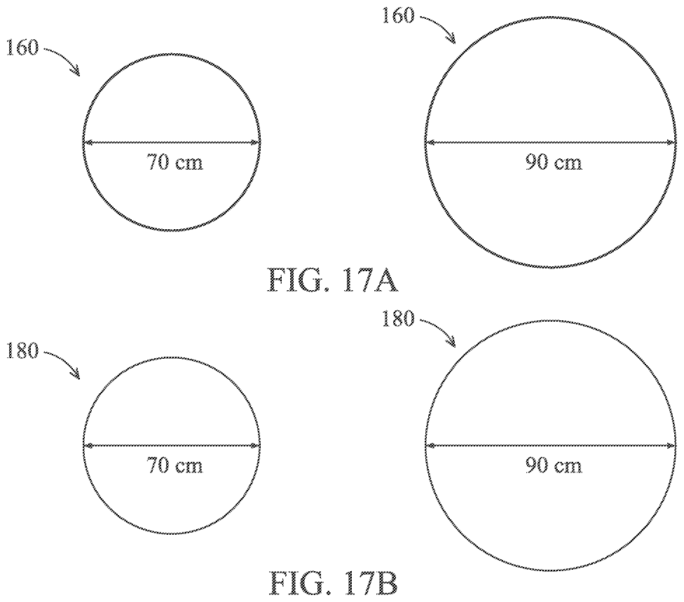

Referring to FIGS. 17A and 17B, the top pad 160 and the sub pad 180 may each have a diameter between about 70 cm and about 90 cm. The top pad 160 and the sub pad 180 may have different diameters, such as the top pad 160 having a smaller diameter than the sub pad 180. However, in most embodiments, the top pad 160 and the sub pad 180 will align with one another and have the same diameter.

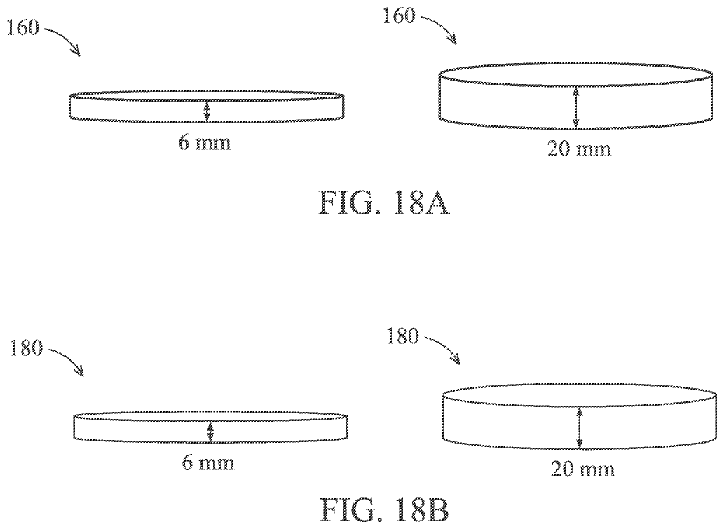

Referring to FIGS. 18A and 18B, the top pad 160 and the sub pad 180 may each have a thickness between about 6 mm and about 20 mm. The top pad 160 and the sub pad 180 may have different thicknesses, such as the top pad 160 having a smaller thickness than the sub pad 180, or vice versa. Alternatively, the top pad 160 and the sub pad 180 may have the same thicknesses.

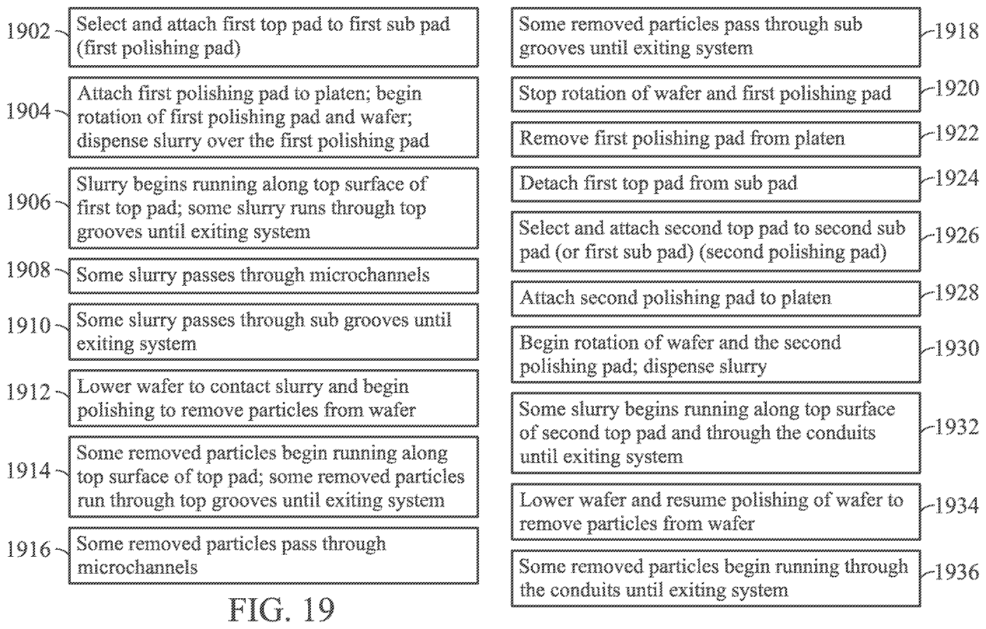

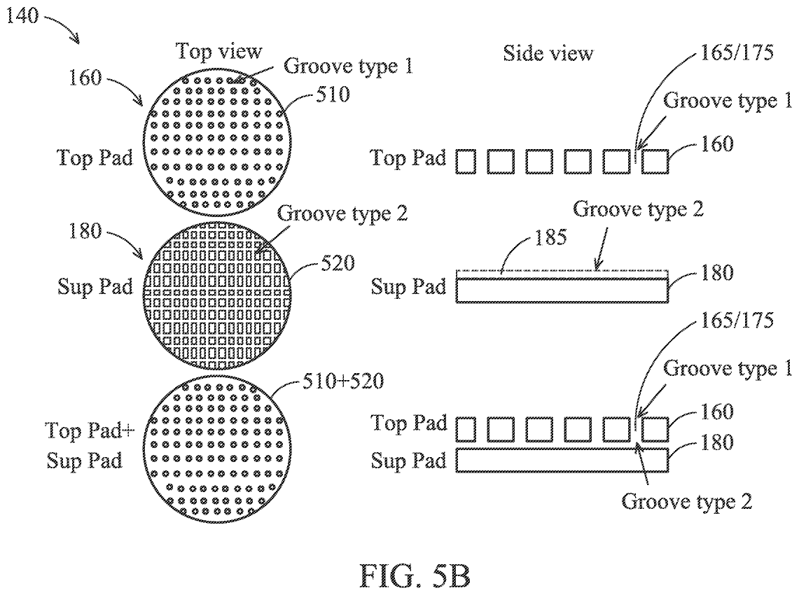

Referring to FIG. 19, the polishing pad 140 effectively breaks off particles from the wafer and removes some of those removed particles from the CMP apparatus to improve the polishing yield. Initially, if the top pad 160 and the sub pad 180 are not attached to one another, the user can select the top pad 160 and the sub pad 180 based on the requirements of the CMP process as discussed previously. The user may then attach them together to form a first polishing pad. When the first polishing pad is attached to the platen, the user may begin rotating the first polishing pad and dispense slurry over it. While most of the slurry remains on the topmost surface of the top pad 160, some of the slurry goes into the top grooves 165. The slurry—whether on the top surface or in the top grooves 165—may generally move in an outward radial direction from the center of the polishing pad due to centrifugal force caused by the rotation. In addition, some of the slurry will travel downward through the microchannels 175. If the microchannels have an outward angle as discussed with respect to FIG. 12D, then the rotation will facilitate this movement as well. The slurry passing through the microchannels 175 will eventually reach the sub grooves 185. Similarly to the slurry on the top surface of the top pad 160 and in the top grooves 165, the slurry in the sub grooves 185 will generally move in an outward direction due to the rotation of the first polishing pad. In both cases (i.e., along the top surface and top grooves 165 of the top pad 160 and along the sub grooves 185 of the sub pad 180), some of the slurry will reach the outer edge of the first polishing pad to be removed from the CMP system. That slurry may then be disposed of or undergo a cleaning process to be recycled back into the CMP process.

The user may begin rotating the wafer and lower it to contact the slurry on the top surface of the first polishing pad. The abrasiveness of the slurry and the rotations of the wafer and the first polishing pad will loosen particles from the surface of the wafer. These removed particles will mix with other components of the slurry. Some of the removed particles will also follow a similar trajectory through the top grooves 165, the microchannels 175, the sub grooves 185, and exit the CMP system similarly as the portion of the slurry discussed above. In other words, the conduit system helps to transport the removed particles out of the CMP system so that they are less likely to remain in the slurry and affect the polishing yield.

After some period of time or degree of polishing, the polishing may be stopped by raising the wafer away from the first polishing pad. The rotation of the first polishing pad may then be stopped in order to remove the first polishing pad. At which point a new combination of the top pad 160 and the sub pad 180 may be selected for latter portions of the CMP process. This can be performed by detaching the initial combination of the top pad 160 and the sub pad 180, cleaning one or both, and replacing one or both with a new top pad 160 and/or a new sub pad 180. The new combination may be attached together to form the second polishing pad. The second polishing pad can then be attached to the platen in order to resume polishing of the wafer. Depending on the needs of the particular CMP step, the replacement with a new top pad 160 and/or a new sub pad 180 can be performed multiple times. In addition, the composition of the slurry may be changed for these latter portions of the CMP process.

A polishing pad comprising a system of conduits to facilitate expelling the slurry, the removed particles, and any other debris during the CMP process will minimize the physical contact that any removed particles and other debris make with the wafer. Minimizing such physical contact will improve the yield and efficiency of the CMP process. For example, because the removed particles and other debris will not have controlled dimensions and compositions (as compared to the specifically selected abrasives), every moment that those removed particles and other debris remain between the wafer and polishing pad, they risk chipping away additional particles from the wafer in such a way that frustrates the planarization of the wafer. On the other hand, if the removed particles are less abrasive than the slurry components, then the removed particles could actually decrease the overall polishing effectiveness.

In an embodiment, a polishing pad includes a top pad and a sub pad below the top pad. The top pad includes grooves along its top surface as well as microchannels running through the top pad from those grooves to a bottom surface. The sub pad also includes grooves along its top surface.

In another embodiment, a CMP system includes a platen, a polishing pad set over the platen, a slurry dispenser directly above one portion of the polishing pad, and a wafer head directly above a different portion of the polishing pad. The polishing pad includes a top pad having grooves and microchannels and a sub pad also having grooves.

In another embodiment, a CMP process includes attaching a top pad to a sub pad to form a polishing pad. The top pad contains top grooves along its top surface and microchannels extending from the top grooves to its bottom surface. The sub pad also contains sub grooves along its top surface. The polishing pad is rotated and slurry is dispensed over it. Some of the slurry moves in an outward radial direction along the top surface of the top pad as well as through the top grooves. In addition, some of the slurry travels downward through the microchannels and then in an outward radial direction through the sub grooves. The slurry that reaches an outer edge of the polishing pad leaves the CMP system and is collected for disposal or recycling. During the CMP process, some of the removed particles from the wafer will travel a similar path as the slurry to leave the CMP system for disposal. At certain times during the CMP process, the polishing may be paused in order to replace the top pad and sub pad with versions having different dimensions of top grooves, microchannels, and/or sub grooves. The CMP process may then resume in a similar fashion as described herein.

In yet another embodiment, a polishing pad includes a top pad having a top surface and a bottom surface as well as a sub pad whose top surface contacts the bottom surface of the top pad. The polishing pad further includes a plurality of conduits, which extend along the top surface of the top pad, through the top pad toward the sub pad, and along the top surface of the sub pad.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A polishing pad, the polishing pad comprising:
a top pad, the top pad comprising:
top grooves along a top surface of the top pad; and
microchannels extending from the top grooves to a bottom surface of the top pad; and
a sub pad below and contacting the top pad, the sub pad comprising sub grooves along a top surface of the sub pad.

2. The polishing pad of claim 1, wherein the top grooves have a first pattern and the sub grooves have a second pattern.

3. The polishing pad of claim 2, wherein the first pattern is the same as the second pattern.

4. The polishing pad of claim 3, wherein the first pattern and second pattern comprise radial lines.

5. The polishing pad of claim 2, wherein the first pattern comprises concentric circles and the second pattern comprises radial lines.

6. The polishing pad of claim 2, wherein the first pattern comprises spirals and the second pattern comprises radial lines.

7. The polishing pad of claim 2, wherein the microchannels align with both the first pattern and the second pattern.

8. The polishing pad of claim 7, wherein the microchannels are slanted to have an angle less than perpendicular with respect to the top surface of the top pad.

9. A chemical-mechanical planarization (CMP) system, the CMP system comprising:
a platen;
a polishing pad disposed over the platen, the polishing pad comprising:
a top pad, the top pad comprising:
top grooves; and
microchannels; and
a sub pad below the top pad, the sub pad comprising sub grooves;
a dispenser disposed above the polishing pad, the dispenser configured to dispense a slurry; and
a head disposed above the polishing pad, the head being laterally displaced from the dispenser.

10. The CMP system of claim 9, wherein the microchannels extend from the top grooves to the sub grooves.

11. The CMP system of claim 10, wherein the microchannels align with the top grooves near a top surface of the top pad, and the microchannels align with the sub grooves near a bottom surface of the top pad.

12. The CMP system of claim 9, wherein in a top-down view the top grooves comprise a first pattern, the sub grooves comprise a second pattern, and the microchannels comprise a third pattern, and wherein the third pattern aligns with the first pattern and the second pattern.

13. The CMP system of claim 12, wherein in a side view cross-section the microchannels comprise a rectangular shape.

14. The CMP system of claim 12, wherein in a side view cross-section the microchannels comprise a trapezoidal shape, wherein the larger base of the trapezoidal shape is adjacent to the top grooves and the smaller base of the trapezoidal shape is adjacent to the sub grooves.

15. The CMP system of claim 12, wherein the first pattern comprises one or more spirals extending from a center region to an outer edge of the top pad, and wherein the second pattern comprises perpendicular grid lines.

16. A method, comprising:
attaching a first top pad to a first sub pad to form a first polishing pad, the first polishing pad comprising:
a first top groove on the first top pad;
a first microchannel extending through the first top pad; and
a first sub groove on the first sub pad;
dispensing a first slurry over the first polishing pad; and
rotating the first polishing pad, wherein some of the first slurry:
first, runs along the first top groove;
second, runs through the first microchannel;
third, runs along the first sub groove; and
fourth, runs off an outer edge of the first polishing pad.

17. The method of claim 16, further comprising:
rotating a wafer disposed above the first polishing pad;
lowering the wafer to contact the first slurry; and
polishing the wafer to remove first particles from the wafer, wherein some of the first particles:
first, run along the first top groove;
second, run through the first microchannel;
third, run along the first sub groove; and
fourth, run off an outer edge of the first polishing pad.

18. The method of claim 17, further comprising:
raising the wafer away from the first polishing pad;
pausing rotation of the wafer and the first polishing pad;
detaching the first top pad from the first sub pad;
attaching a second top pad to a second top pad to form a second polishing pad;
dispensing a second slurry over the second polishing pad;
rotating the second polishing pad;
rotating the wafer;
lowering the wafer to contact the second slurry; and
resuming polishing the wafer to remove second particles from the wafer.

19. The method of claim 18, wherein the second polishing pad comprises:
a second top groove on the second top pad;
a second microchannel extending through the second top pad; and
a second sub groove on the second sub pad.

20. The method of claim 19, wherein during the polishing the wafer to remove second particles, some of the second particles:
first, run along the second top groove;
second, run through the second microchannel;
third, run along the second sub groove; and
fourth, run off an outer edge of the second polishing pad.
